(19) United States
(12) Patent Application Publication
(10) Pub. No.: US 2006/0189152 A1
(43) Pub. Date: Aug. 24, 2006

(54) Slurry composition, method of polishing an object and method of forming a contact in a semiconductor device using the slurry composition

(76) Inventors: Ki-Hoon Jang, Seoul (KR); Yong-Sun Ko, Gyeonggi-do (KR); Kyung-Hyun Kim, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/323,356

(22) Filed: Dec. 29, 2005

(30) Foreign Application Priority Data
Dec. 30, 2004 (KR) 2004-116171

(51) Int. Cl. H01L 21/00; H01L 21/31

(52) U.S. Cl. 438/759; 438/28

(57) ABSTRACT

In a slurry composition preventing damage to an insulation layer, and uniformly polishing a metal layer, the slurry composition includes an acidic aqueous solution having a first pH and an anionic surfactant having a second pH lower than or equal to the first pH. Irregular polishing of the metal layer relative to a pattern density may be prevented and a contact having a uniform thickness may be formed using the slurry composition.

### CROSS REFERENCE TO RELATED APPLICATIONS

This application claims priority under 35 USC § 119 to Korean Patent Application No. 2004-116171 filed on Dec. 30, 2004, the contents of which are herein incorporated by reference in their entirety.

### BACKGROUND OF THE INVENTION

1. Field of the Invention

The present invention relates to a slurry composition, a method of polishing an object and a method of forming a contact in a semiconductor device using the slurry composition.

2. Description of the Related Art

Semiconductor devices having high integration degree and rapid response speed are desired as information processing apparatuses have been developed. Hence, the technology of manufacturing the semiconductor devices has been developed to improve integration degree, reliability and response speed of the semiconductor devices.

A reactive ion etching (RIE) process has been used to remove a metal such as tungsten (W) from a substrate in a semiconductor manufacturing process. Through the RIE process, a metal layer is excessively etched and even the metal layer included in a via is partially removed from the substrate. Thus, the metal layer included in a via does not make contact with a metal wiring formed in a subsequent process. In addition, impurities on a semiconductor substrate, which are generated in the RIE process, cause operation failures of the semiconductor device.

To overcome the above problems, a chemical mechanical polishing (CMP) process has been developed. The metal layer is effectively planarized through the CMP process. As a semiconductor device having a high integration degree utilizes a multi-layered structure, the CMP process has been widely used in a planarization of the metal layer and an insulation layer. Thus, various slurry compositions that are applied to the CMP process of the metal layer have been developed.

Examples of slurry compositions are disclosed in U.S. Pat. No. 5,980,775 issued to Grumbine, et al., and U.S. Pat. No. 5,958,288 issued to Mueller, et al. Here, the slurry compositions include peroxide as the oxidizing agent, and a metal catalyst for improving the oxidizing activity of the oxidizing agent to increase the polishing rate. U.S. Pat. No. 5,340,370 issued to Cadien, et al. and U.S. Pat. No. 5,527,423 issued to Neville, et al. disclose slurry compositions including an excessive amount of the oxidizing agent to obtain a high polishing rate.

However, the conventional slurry compositions used in the CMP process have several problems. Due to a difference in the polishing rate between the metal layer and the insulation layer, erosion of the metal layer, damage to the insulation layer and dishing phenomena are generated, and defects of the semiconductor device are also generated in a subsequent process.

FIGS. 1 and 2 are cross-sectional views illustrating a tungsten layer 14 polished using the conventional slurry compositions. Referring to FIG. 1, the tungsten layer 14 is formed on a substrate 10 on which a line pattern 12 is formed. Referring to FIG. 2, the tungsten layer 14 is polished through the CMP process until an upper surface of the line pattern is exposed. Erosion of the tungsten layer 14 and damage to the line pattern 12 are more severely generated in a densely patterned region of the line pattern 12 than those of a sparsely patterned region. Thus, a thickness of the line pattern 12 in the densely patterned region is reduced in the CMP process. When a metal layer is over-polished to remove impurities generated in the CMP process, the thickness of the pattern is excessively reduced. When the metal layer is eroded and/or an insulation layer (e.g. an oxide layer) is damaged in the CMP process, the metal layer is not electrically connected to upper structures including a metal such as aluminum or tungsten, and operation failures of the semiconductor device are generated. Therefore, there is still required a slurry composition that selectively polishes the metal layer relative to the insulation layer, and prevents erosion of the metal layer and damage to the oxide layer even in the densely patterned region.

### SUMMARY OF THE INVENTION

Embodiments of the present invention can provide slurry compositions having a high polishing selectivity. Embodiments of the present invention can also provide methods of polishing an object using the above slurry compositions. Embodiments of the present invention still can also provide methods of forming a contact in a semiconductor device using the above slurry compositions.

According to one aspect of the present invention, a slurry composition includes an acidic aqueous solution having a first pH and an anionic surfactant having a second pH lower than or equal to the first pH. The anionic surfactant may preferably comprise at least one of a phosphoric acid compound, a phosphate compound, a sulfonic acid compound, a sulfonate compound, a carboxylic acid compound, a carboxylate compound, an acrylic acid compound and an acrylate compound. More preferably, the anionic surfactant may comprise the phosphate compound. Furthermore, the phosphate compound may most preferably comprise a polyoxyalkylene alkyl aryl phosphate compound. The anionic surfactant may preferably comprise an oxyalkylene chain. The oxyalkylene chain may be selected from the group consisting of oxymethylene chain, oxyethylene chain, oxypropylene chain and oxybutylene chain. The oxyalkylene chain may also preferably have a number of oxyalkylene repeating units of from about 20 up to about 60.

The anionic surfactant may preferably comprise an alkyl chain having from 1 up to 40 carbon atoms. The alkyl chain may more preferably have from 1 up to 20 carbon atoms.

The slurry composition may preferably have a first pH that is from about 1 up to about 6, more preferably from about 1 up to about 5, and most preferably from about 2 up to about 6.

The slurry composition preferably may have a second pH that is from about 1 up to about 5, more preferably from about 1 up to about 4, and most preferably from about 2 up to about 5.

The acidic aqueous solution may comprise an oxidizing agent, an abrasive and water. The oxidizing agent may comprise a peroxide compound, a ferric compound, or a mixture thereof. The peroxide compound may comprise at least one of hydrogen peroxide, benzoyl peroxide, calcium peroxide, barium peroxide and sodium peroxide. The ferric compound may comprise at least one of ferric nitrate, potassium ferricyanide, ferric phosphate and ferric sulfate. The abrasive may comprise at least one of silica, alumina, ceria, zirconia and titania.

The slurry composition may further comprise a pH-controlling agent.

The pH-controlling agent may comprise at least one base of potassium hydroxide, ammonium hydroxide, sodium hydroxide, tetramethylammonium hydroxide and choline, or at least one acid selected from the group consisting of sulfuric acid, hydrochloric acid, phosphoric acid, nitric acid and acetic acid.

The slurry composition may preferably comprise from about 0.001 up to about 10 parts by weight of the anionic surfactant, based on about 1,000 parts by weight of the slurry composition. More preferably, the slurry composition may comprise from about 0.01 up to about 5 parts by weight of the anionic surfactant, based on about 1,000 parts by weight of the slurry composition.

A method of polishing an object is also provided. This method comprises preparing an object, introducing a slurry composition to a polishing pad, the slurry composition including an acidic aqueous solution having a first pH and an anionic surfactant having a second pH lower than or equal to the first pH, and polishing a surface of the object by contacting the polishing pad and the surface of the object. The step of preparing the object may further preferably comprise forming an insulation layer on a substrate, the insulation layer including an opening, and then forming a metal layer on the insulation layer to fill the opening. The method may further preferably provide the step of polishing the surface of the object, which is performed until an upper surface of the insulation layer is exposed. The insulation layer may preferably comprise an oxide. The metal layer may preferably comprise tungsten, and further it may preferably comprise aluminum or copper.

A method of forming a contact in a semiconductor device is also provided. This method comprises providing a substrate, forming an insulation layer on said substrate, said substrate including a lower structure, partially removing the insulation layer to form a contact hole exposing a portion of the lower structure, forming a conductive layer on the insulation layer which fills the contact hole, and chemically and mechanically polishing the conductive layer with a slurry composition including an acidic aqueous solution having a first pH, and an anionic surfactant having a second pH lower than or equal to the first pH, until an upper surface of the insulation layer is exposed. The insulation layer may preferably comprise an oxide and the conductive layer may preferably comprise at least one of tungsten, aluminum and copper.

According to the present invention, a metal layer formed on a substrate may be effectively polished using the slurry composition. Damage to the metal layer may be prevented, and irregular polishing of the metal layer relative to a pattern density may be prevented to thereby form a contact having a uniform thickness. Therefore, a semiconductor device having improved reliability may be efficiently manufactured, and a productivity of a semiconductor manufacturing process may be enhanced.

### BRIEF DESCRIPTION OF THE DRAWINGS

The above and other features and advantages of the present invention will become more apparent by describing in detailed exemplary embodiments thereof with reference to the accompanying drawings, in which:

FIGS. 1 and 2 are cross-sectional views illustrating a tungsten layer polished using a conventional slurry composition;

FIGS. 3 and 4 are perspective views illustrating a mechanism of passivating a layer with an anionic surfactant in a slurry composition in accordance with an example embodiment of the present invention;

FIG. 5 is a flow chart illustrating a method of polishing an object in accordance with an example embodiment of the present invention;

FIGS. 6 to 9 are cross-sectional views illustrating a method of forming a contact in a semiconductor device in accordance with an embodiment of the present invention;

FIGS. 10 to 15 are cross-sectional views illustrating a method of forming a contact in a semiconductor device in accordance with another embodiment of the present invention; and

FIG. 16 is a graph illustrating a thickness of a bit line pattern formed on each portion of a wafer when the bit line pattern is formed using slurry compositions prepared in Examples 2, 3 and 6 and Comparative Example.

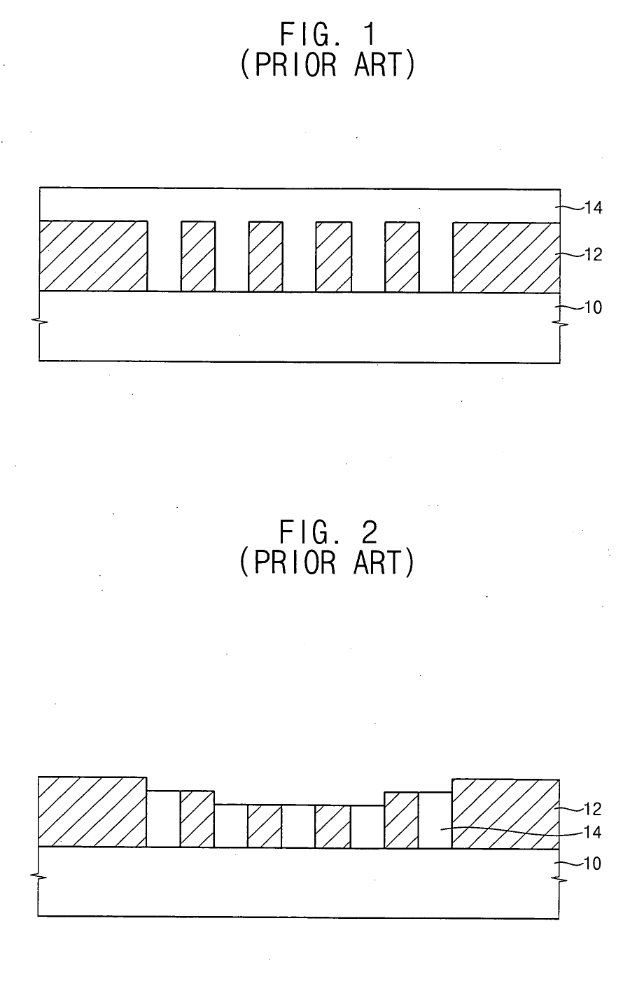

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Slurry Composition

In order to efficiently polish an object including a metal layer and/or an insulation layer without generating damages to the metal layer and the insulation layer, a slurry composition may be required to have some characteristics as follows.

Firstly, the slurry composition preferably has a minimized corrodibility with respect to a metal such as tungsten that may be exposed in the polishing process and is disposed inside a via. Particularly, an oxidizing agent in the slurry composition may corrode the metal layer including tungsten. Thus, the slurry composition may prevent corrosion of the metal layer exposed in a polishing process.

Additionally, the insulation layer which serves as a polishing stop layer may be damaged in a polishing process. Particularly, the insulation layer in a densely patterned region may be severely damaged in the polishing process, so that a contact having a uniform thickness may not be formed. Thus, the slurry composition capable of preventing damage to the insulation layer is preferably provided.

To satisfy the above characteristics, the slurry composition of the present invention includes an acidic aqueous solution having a first pH and an anionic surfactant having a second pH. Here, the second pH of the anionic surfactant may be lower than or equal to the first pH of the acidic aqueous solution. When the second pH of the anionic surfactant is higher than the first pH of the acidic aqueous solution, the anionic surfactant may lose anionic characteristics, so that the insulation layer may not be effectively passivated by the anionic surfactant.

The anionic surfactant of the present invention may be adsorbed onto the insulation layer (e.g. an oxide layer) to thereby prevent damage to that insulation layer. Particularly, the anionic surfactant may be electrostatically adsorbed onto a surface of the insulation layer to form a passivation layer on the insulation layer. Thus, the slurry composition of the present invention may polish a metal layer with a high degree of selectivity relative to the insulation layer, and prevent damage to the insulation layer in the polishing process.

A slurry composition for polishing a metal layer generally has an acidic pH value. In an acidic condition, a surface of the metal layer may be negatively charged and a surface of the insulation layer such as an oxide layer may be positively charged. Thus, the anionic surfactant in the slurry composition may be strongly adsorbed onto the surface of the insulation layer by an electrostatic attraction to thereby passivate the insulation layer, and electrostatic repulsion may be also generated between the surface of the metal layer and the anionic surfactant.

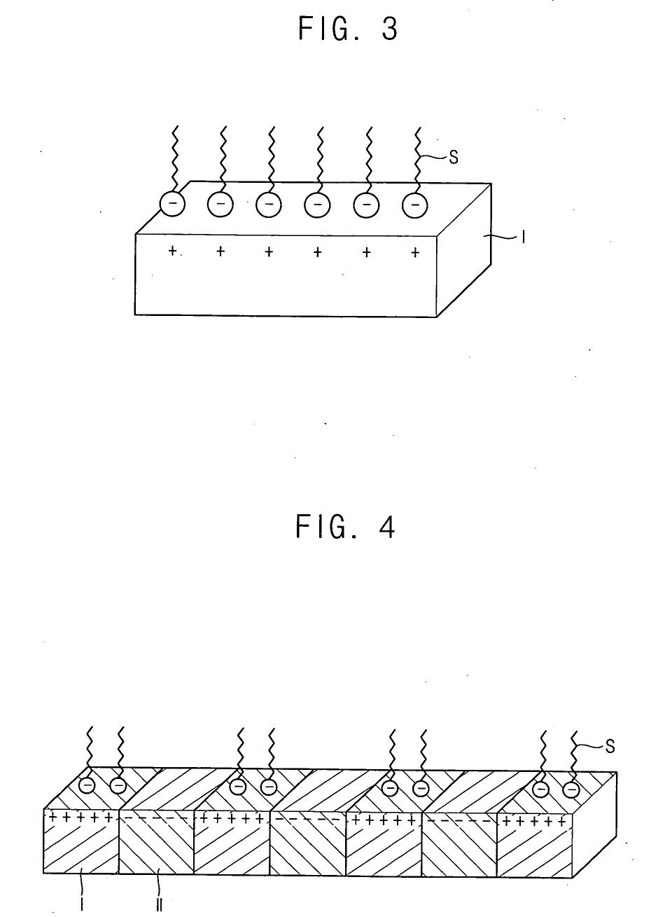

FIGS. 3 and 4 are perspective views illustrating a mechanism of passivating a layer with the anionic surfactant included in the slurry composition. Particularly, FIG. 3 is a perspective view illustrating a mechanism of passivating the insulation layer (I) with the anionic surfactant (S). FIG. 4 is a perspective view illustrating a mechanism of selectively passivating the insulation layer (I) relative to the metal layer (II) with the anionic surfactant (S).

Referring to FIGS. 3 and 4, the anionic surfactant (S) may selectively passivate the insulation layer (I) (e.g. an oxide layer) relative to the metal layer (II) (e.g. a tungsten layer). In the polishing process, the slurry composition may selectively polish a negatively charged layer, and prevent a positively charged layer from being polished.

Examples of the anionic surfactant that may be used in the slurry composition of the present invention may include a phosphoric acid compound, a phosphate compound, a sulfonic acid compound, a sulfonate compound, a carboxylic acid compound, a carboxylate compound, an acrylic acid compound, an acrylate compound, etc. These can be used alone or in a mixture thereof. The phosphate compound has a sufficiently low pH to easily maintain anionic characteristics in the slurry composition and to effectively passivate the insulation layer having a positive charge. Therefore, the slurry composition of the present invention may advantageously include the phosphate compound such as a polyoxyalkylene alkyl aryl phosphate compound. The polyoxyalkylene alkyl aryl phosphate compound is represented by a following chemical formula 1.

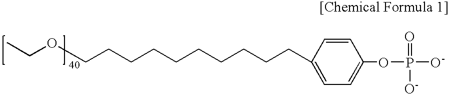

A surfactant including an oxyalkylene chain has a hydrophilic characteristic to be easily dissolved in water. Therefore, the anionic surfactant of the slurry composition may advantageously include the oxyalkylene chain. Examples of the oxyalkylene chain may include oxymethylene chain, oxyethylene chain, oxypropylene chain, oxybutylene chain, etc. These can be used alone or in a combination thereof.

When the oxyalkylene chain has an oxyalkylene repeating unit of less than about 20, water solubility of the anionic surfactant may be lowered. In addition, when the number of the oxyalkylene repeating unit is greater than about 60, viscosity of the slurry composition may excessively increase so that an object may not be uniformly polished. Thus, the anionic surfactant in the slurry composition of the present invention may preferably include the oxyalkylene chain having a number of oxyalkylene repeating units of from about 20 up to about 60.

In an embodiment of the present invention, the anionic surfactant may include an alkyl chain. When the alkyl chain has more than about 40 carbon atoms, a polishing rate of the metal layer may be deteriorated. Thus, the anionic surfactant in the slurry composition of the present invention may preferably include an alkyl chain having from about 1 to about 40 carbon atoms, more preferably, an alkyl chain having from about 1 to about 20 carbon atoms.

When the content of the anionic surfactant is less than about 0.001 part by weight based on about 1,000 parts by weight of the slurry composition, the anionic surfactant may not effectively protect the insulation layer such as the oxide layer. In addition, when the slurry composition includes greater than about 10 parts by weight of the anionic surfactant, the polishing rate may be lowered and a process efficiency may be deteriorated. Thus, the slurry composition of the present invention may preferably include from about 0.001 up to about 10 parts by weight of the anionic surfactant, more preferably, from about 0.01 up to about 5 parts by weight of the anionic surfactant, based on about 1,000 parts by weight of the slurry composition.

The slurry composition of the present invention includes the anionic surfactant to prevent the insulation layer from being damaged, and also the acidic aqueous solution to efficiently polish the metal layer. The acidic aqueous solution may also include an oxidizing agent, an abrasive and water.

The oxidizing agent in the slurry composition, in general, may chemically oxidize the metal layer, and then the abrasive may mechanically polish the metal layer. Examples of preferred oxidizing agent that may be used in the slurry composition of the present invention may include a peroxide compound, a ferric compound and a mixture thereof. Although the peroxide compound has a high reduction potential and a relatively high oxidizing ability, the peroxide compound has a relatively low reaction rate with metal, so that the oxidation rate of the metal and the etch rate of metal oxide are relatively low. On the other hand, though the ferric compound has a low reduction potential and a relatively low oxidizing ability, the ferric compound has a reaction rate with the metal which is relatively higher than that of the peroxide compound, thereby rapidly oxidizing the metal. When the polishing process is performed using the slurry composition including both the peroxide compound and the ferric compound as the oxidizing agent, first oxidation-reduction reactions of the ferric compound with metal may occur, so that the metal may be oxidized and the ferric compound may be reduced. Simultaneously, second oxidation-reduction reactions of the peroxide compound with the ferric compound may be generated so that the peroxide compound may oxidize the reduced ferric compound to thereby renew the oxidizing ability of the ferric compound. Then, the renewed ferric compound may contribute to the first oxidation-reduction reactions again. Due to circulation of the first and second oxidation-reduction reactions, a small amount of the oxidizing agent may efficiently remove the metal. Therefore, the slurry composition of the present invention may advantageously include both the peroxide compound and the ferric compound as the oxidizing agent.

Examples of peroxide compound that may be used in the slurry composition of the present invention may include hydrogen peroxide, benzoyl peroxide, calcium peroxide, barium peroxide, sodium peroxide, etc. These can be used alone or in a mixture thereof.

Examples of ferric compound may that may be used in the slurry composition of the present invention include ferric nitrate, potassium ferricyanide, ferric phosphate, ferric sulfate, etc. These can be used alone or in a mixture thereof.

As described above, the oxidizing agent in the slurry composition may oxidize metal in the metal layer to form metal oxide, and the abrasive may mechanically polish the metal oxide to remove the metal oxide from the object such as a substrate. Therefore, the metal layer may be planarized through repeated chemical polishing of the oxidizing agent and mechanical polishing of the abrasive.

Examples of the abrasive that may be used in the slurry composition of the present invention may include silica, alumina, ceria, zirconia, titania, etc. These can be used alone or in a mixture thereof.

The slurry composition of the present invention includes water, preferably pure water, more preferably ultra pure water or deionized water.

In an example embodiment of the present invention, the slurry composition may further include a pH-controlling agent in order to properly adjust the pH of the slurry composition in the polishing process. Examples of the pH-controlling agent that may be used in the slurry composition of the present invention may include a base such as potassium hydroxide, ammonium hydroxide, sodium hydroxide, tetramethylammonium hydroxide, choline, etc., or an acid such as sulfuric acid, hydrochloric acid, phosphoric acid, nitric acid, acetic acid, etc. These can be used alone or in a mixture thereof.

Each of the acidic aqueous solution and the anionic surfactant in the slurry composition may have a proper pH in accordance with types of the object. Particularly, when the object includes a metal such as tungsten, aluminum, etc., the acidic aqueous solution may preferably have a first pH in a range of about 1 to about 6, and the anionic surfactant may preferably have a second pH in a range of about 1 to about 5, because the slurry composition may have an excellent polishing effect in the pH ranges.

In an embodiment of the present invention, the slurry composition may include the acidic aqueous solution of the first pH having an oxidizing agent, an abrasive and pure water, and the anionic surfactant having a second pH lower than or equal to the first pH. Alternatively, the slurry composition may further include the pH-controlling agent. The acidic aqueous solution, the anionic surfactant, the oxidizing agent, the abrasive, pure water and the pH-controlling agent are substantially identical to those described above so that the description will be omitted.

Method of Polishing An Object

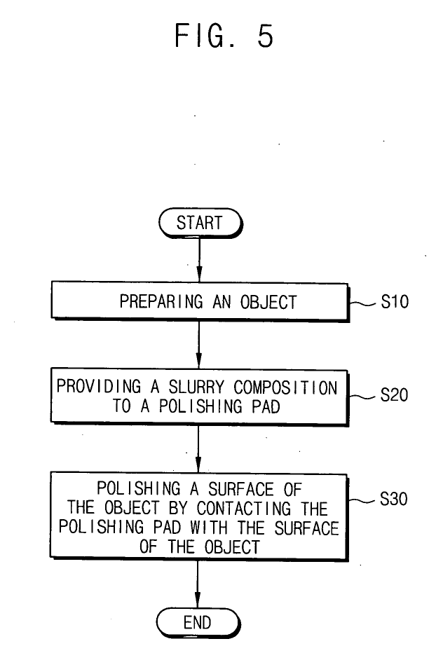

FIG. 5 is a flow chart illustrating a method of polishing an object in accordance with an example embodiment of the present invention.

Referring to FIG. 5, the object is prepared in step S10. Particularly, an insulation layer including an opening may be formed on a substrate, and then a metal layer may be formed on the insulation layer to fill up the opening. The insulation layer may include an oxide, and the metal layer may include a metal such as tungsten, aluminum, copper, etc.

After the object is prepared, a slurry composition is provided to a polishing pad in step S20. The slurry composition includes an acidic aqueous solution having a first pH and an anionic surfactant having a second pH lower than or equal to the first pH. A surface of the object is polished by contacting the polishing pad with the surface of the object in step S30. In the polishing process, the polishing pad and the object are revolved. The polishing pad may rotate in a direction substantially identical to that of the object. Alternatively, the polishing pad may rotate along a direction substantially opposite to that of the object. Polishing the surface of the object may be performed until an upper surface of the insulation layer is exposed.

The object including the metal layer may be pressurized while making contact with the polishing pad. Thus, the object may be chemically polished by the slurry composition, and also mechanically polished by rotation and pressurization of the object. In addition, the oxidizing agent in the slurry composition may oxidize metal in the metal layer to form metal oxide, and also the abrasive in the slurry composition may contribute to mechanically polish the metal oxide. Examples of the oxidizing agent may include the peroxide compound, the ferric compound, etc. Examples of the abrasive may include silica, ceria, titania, alumina, etc.

The slurry composition may have a proper pH in accordance with types of the object. The acidic aqueous solution may preferably have the first pH in a range of about 1 to about 6, and the anionic surfactant may preferably have the second pH in a range of about 1 to about 5, because the slurry composition may have an excellent polishing effect in the pH ranges. Particularly, when the metal layer includes tungsten, the acidic aqueous solution may preferably have the first pH in a range of about 1 to about 5, and the anionic surfactant may preferably have the second pH in a range of about 1 to about 4. When the metal layer includes copper or aluminum, the acidic aqueous solution may preferably have the first pH in a range of about 2 to about 6, and the anionic surfactant may preferably have the second pH in a range of about 2 to about 5.

Method of Forming A Contact In A Semiconductor Device

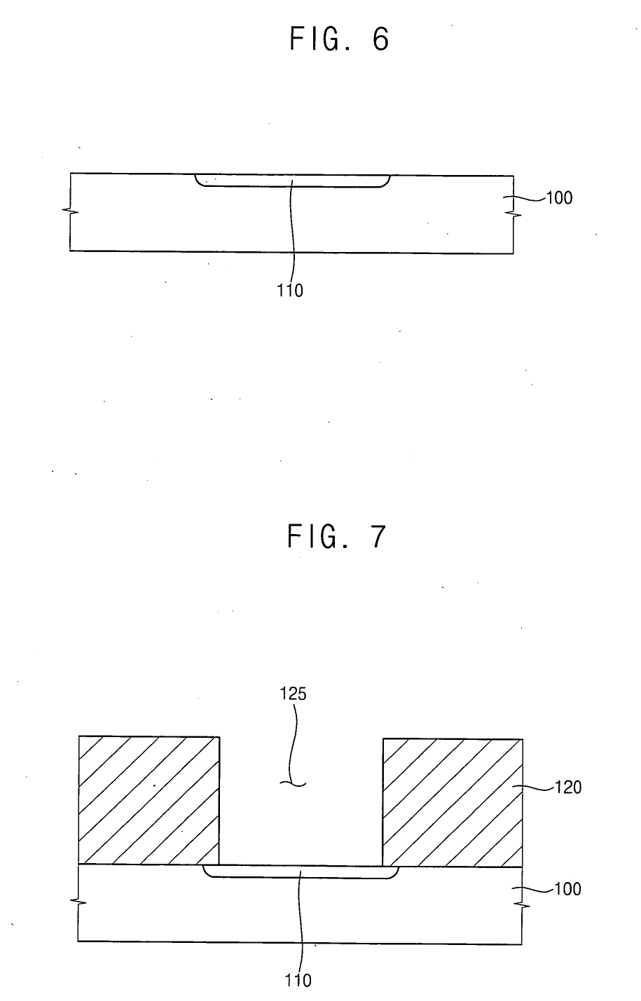

FIGS. 6 to 9 are cross-sectional views illustrating a method of forming a contact in a semiconductor device in accordance with one embodiment of the present invention.

FIG. 6 is a cross-sectional view illustrating a contact region 110 formed on the substrate 100. FIG. 7 is a cross-sectional view illustrating a step of forming an insulation layer 120 including a contact hole 125 on the substrate 100.

Referring to FIGS. 6 and 7, contact region 110 is formed on the substrate 100. The insulation layer 120 is formed on the substrate 100. The insulation layer 120 may be formed using an oxide such as boro-phosphor silicate glass (BPSG), phosphor silicate glass (PSG), undoped silicate glass (USG), spin on glass (SOG), plasma enhanced-tetraethyl orthosilicate (PE-TEOS), high density plasma-chemical vapor deposition (HDP-CVD) oxide, etc.

The insulation layer 120 is partially removed to form the contact hole 125 exposing the contact region 110. The contact region 110 may be partially or entirely exposed through the contact hole 125. Particularly, after a photoresist pattern (not shown) may be formed on the insulation layer 120, the insulation layer 120 may be anisotropically etched using the photoresist pattern as an etching mask to thereby form the contact hole 125.

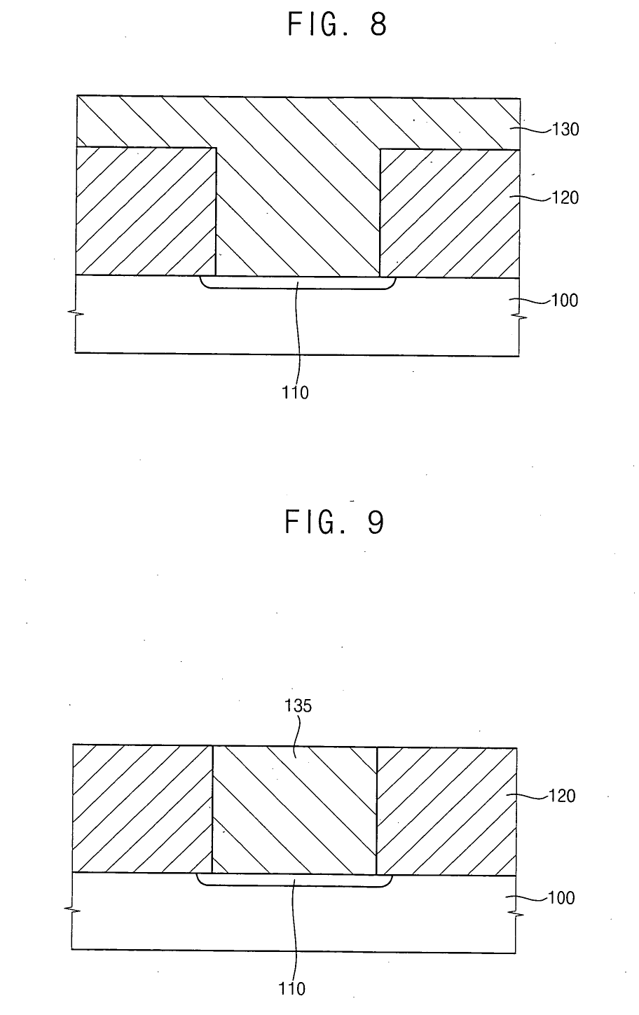

FIG. 8 is a cross-sectional view illustrating a step of forming a conductive layer 130 on the insulation layer 120.

Referring to FIG. 8, the conductive layer 130 is formed on the insulation layer 120 to fill up the contact hole 125. Particularly, after the photoresist pattern is removed using ashing and/or stripping processes, the conductive layer 130 may be formed using a conductive material such as a metal, a metal nitride, polysilicon doped with impurities, etc. Examples of the metal may include tungsten, aluminum, copper, etc. Examples of the metal nitride may include titanium nitride, tungsten nitride, etc. In an example embodiment of the present invention, the conductive layer 130 may be advantageously formed using a metal such as tungsten, aluminum, copper, etc. For example, the conductive layer 130 may be formed using tungsten.

FIG. 9 is a cross-sectional view illustrating a step of forming a contact 135 on the substrate 100.

Referring to FIG. 9, the conductive layer 130 is chemically and mechanically polished using a slurry composition including an acidic aqueous solution having a first pH and an anionic surfactant having a second pH lower than or equal to the first pH. When the conductive layer 130 includes a metal such as tungsten and the insulation layer 120 includes an oxide such as silicon oxide, the acidic aqueous solution may preferably have the first pH in a range of about 1 to about 6, and the anionic surfactant may preferably have the second pH in a range of about 1 to about 5. In these pH ranges, the insulation layer 120 may have a positive charge and the conductive layer 130 may have a negative charge. The anionic surfactant in the slurry composition may be strongly adsorbed onto the surface of the insulation layer 120 due to an electrostatic attraction to passivate the insulation layer 120, and also electrostatic repulsion may be generated between the surface of the conductive layer 130 and the anionic surfactant. Thus, the anionic surfactant in the slurry composition may prevent the insulation layer 120 having the positive charge from being damaged, and also selectively polish the conductive layer 130 having the negative charge.

The conductive layer 130 may be polished until the upper surface of the insulation layer 120 is exposed, thereby forming the contact 135 of a semiconductor device.

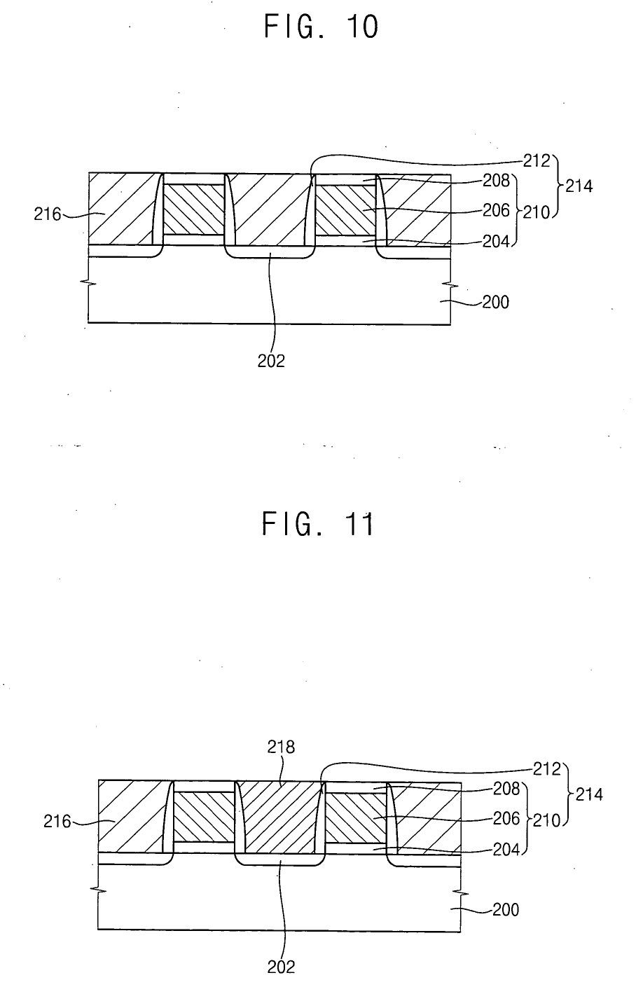

FIGS. 10 to 15 are cross-sectional views illustrating a method of forming a contact in a semiconductor device in accordance with another example embodiment of the present invention.

FIG. 10 is a cross-sectional view illustrating a step of forming a first insulation layer 216 on a semiconductor substrate 200.

Referring to FIG. 10, an isolation layer (not shown) is formed on the semiconductor substrate 200. The isolation layer may be formed by an isolation process such as a shallow trench isolation (STI) process or a local oxidation of silicon (LOCOS). The semiconductor substrate 200 is divided into an active region (not shown) and a field region (not shown) by forming the isolation layer. A gate oxide layer pattern 204, a gate conductive layer pattern 206 and a gate mask 208 are successively formed on the semiconductor substrate 200 to form a gate structure 210 on the semiconductor substrate 200. A nitride layer is formed on the semiconductor substrate 200 to cover the gate structure 210. The nitride layer may be formed using a nitride such as silicon nitride. The nitride layer is anisotropically etched to form a gate spacer 212 on a sidewall of the gate structure 210. Therefore, word lines 214, each of which includes the gate structure 210, and the gate spacer 212 are formed on the semiconductor substrate 200.

Impurities are doped into the semiconductor substrate 200 exposed between the word lines 214 through an ion implantation process. The impurities may be implanted into the semiconductor substrate 200 using the word lines 214 as masks, and then the semiconductor substrate 200 may be thermally treated so that source/drain regions 202 are formed at upper portions of the semiconductor substrate 200. As a result, the semiconductor substrate 200 including a lower structure may be formed.

The first insulation layer 216 is formed on the semiconductor substrate 200 to cover the word lines 214. The first insulation layer 216 may be formed using an oxide such as boro-phosphor silicate glass (BPSG), phosphor silicate glass (PSG), undoped silicate glass (USG), spin on glass (SOG), plasma enhanced-tetraethyl orthosilicate (PE-TEOS), high density plasma-chemical vapor deposition (HDP-CVD) oxide, etc.

The first insulation layer 216 is partially removed until upper surfaces of the word lines 214 are exposed. An upper surface of the first insulation layer 216 may be planarized by a chemical mechanical polishing (CMP) process, an etch back process, or a combination process comprising the CMP and the etch back.

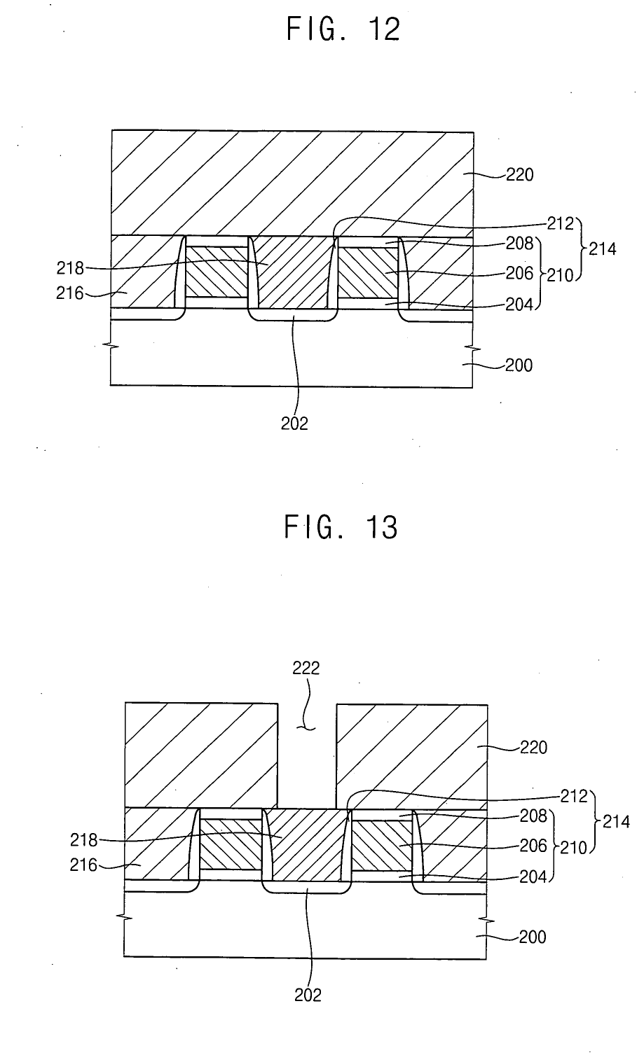

FIG. 11 is a cross-sectional view illustrating a step of forming a contact pad 218 on the semiconductor substrate 200.

Referring to FIG. 11, the insulation layer is partially removed to form a first contact hole (not shown) exposing a predetermined portion of the source/drain regions 202. After a photoresist pattern (not shown) is formed on the first insulation layer 216, the first insulation layer 216 may be anisotropically etched using the photoresist pattern as an etching mask to thereby form the first contact hole exposing the source/drain regions 202.

After formation of the first contact hole, the first conductive layer is formed on the first insulation layer 216 to fill up the first contact hole. Particularly, after the photoresist pattern is removed using ashing and/or stripping processes, the first conductive layer may be formed using a conductive material such as a metal, a metal nitride, polysilicon doped with impurities, etc. Examples of the metal may include tungsten, aluminum, copper, etc. An example of the metal nitride may include titanium nitride. In an embodiment of the present invention, the first conductive layer may be advantageously formed using a metal such as tungsten, aluminum, copper, etc. For example, the first conductive layer may be formed using tungsten. Subsequently, the first conductive layer is chemically and mechanically polished using a slurry composition including an acidic aqueous solution having a first pH and an anionic surfactant having a second pH lower than or equal to the first pH. The first conductive layer may be polished until an upper surface of the first insulation layer 216 is exposed, thereby forming the contact pad 218 on the semiconductor substrate 200.

FIG. 12 is a cross-sectional view illustrating a step of forming a second insulation layer 220 on the word lines 214, the contact pad 218 and the first insulation layer 216.

Referring to FIG. 12, the second insulation layer 220 is formed on the word lines 214, the contact pad 218 and the first insulation layer 216. The second insulation layer 220 may be formed using a material different from that of the first insulation layer 216. The second insulation layer 220 may be formed using an oxide such as boro-phosphor silicate glass (BPSG), phosphor silicate glass (PSG), undoped silicate glass (USG), spin on glass (SOG), plasma enhanced-tetraethyl orthosilicate (PE-TEOS), high density plasma-chemical vapor deposition (HDP-CVD) oxide, etc.

FIG. 13 is a cross-sectional view illustrating a step of forming a second contact hole 222 in the second insulation layer 220.

Referring to FIG. 13, the second insulation layer 220 is partially removed to form second contact hole 222 exposing a predetermined portion of the contact pad 218. Particularly, after a photoresist pattern (not shown) is formed on the second insulation layer 220, the second insulation layer 222 may be anisotropically etched using the photoresist pattern as an etching mask to thereby form the second contact hole 222 exposing the contact pad 218.

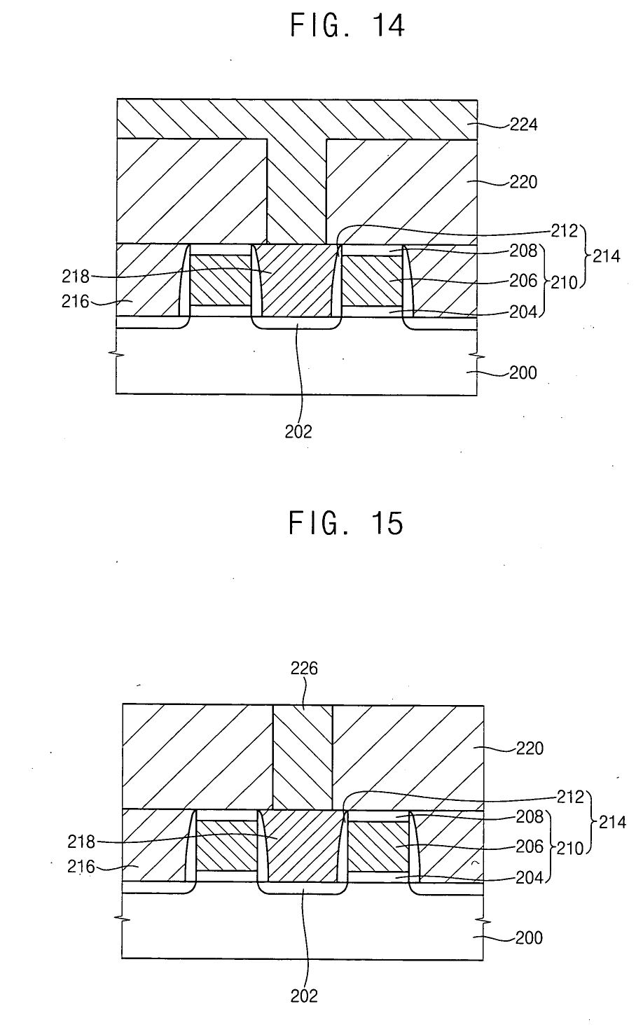

FIG. 14 is a cross-sectional view illustrating a step of forming a second conductive layer 224 on the second insulation layer 220.

Referring to FIG. 14, second conductive layer 224 is formed on the second insulation layer 220 to fill up the second contact hole 222. Particularly, after the photoresist pattern may be removed using ashing and/or stripping processes, the second conductive layer 224 may be formed using a conductive material different from that of the first conductive layer. For example, the second conductive layer 224 may be formed using the conductive material such as a metal, a metal nitride, polysilicon doped with impurities, etc. Examples of the metal may include tungsten, aluminum, copper, etc. An example of the metal nitride may include titanium nitride. In an example embodiment of the present invention, the first conductive layer may be advantageously formed using a metal such as tungsten, aluminum, copper, etc. For example, the first conductive layer may be formed using tungsten.

FIG. 15 is a cross-sectional view illustrating a step of forming a contact 226 on the contact pad 218.

Referring to FIG. 15, the second conductive layer 224 is chemically and mechanically polished using a slurry composition including an acidic aqueous solution having a first pH and an anionic surfactant having a second pH lower than or equal to the first pH. When the second conductive layer 224 includes a metal such as tungsten and the second insulation layer 220 includes an oxide such as silicon oxide, the acidic aqueous solution may preferably have the first pH in a range of about 1 to about 6, and the anionic surfactant may preferably have the second pH in a range of about 1 to about 5. In the pH ranges, the second insulation layer 220 may have a positive charge and the second conductive layer 224 may have a negative charge. The anionic surfactant in the slurry composition may be strongly adsorbed onto the surface of the second insulation layer 220 due to an electrostatic attraction to passivate the second insulation layer 220, and also electrostatic repulsion may be generated between the surface of the second conductive layer 224 and the anionic surfactant. Thus, the anionic surfactant in the slurry composition may prevent the second insulation layer 220 having the positive charge from being polished, and also selectively polish the second conductive layer 224 having the negative charge.

The second conductive layer 224 may be polished until an upper surface of the second insulation layer 220 is exposed, thereby forming the contact 226 of a semiconductor device on the contact pad 218.

The slurry composition of the present invention will be further described through Examples and Comparative Example hereinafter.

Preparation of A Slurry Composition

### EXAMPLE 1

A slurry composition was prepared by mixing about 500 parts by weight of SSW2000 (trade name manufactured by Microelectronics Co., U.S.A.) slurry composition, about 66 parts by weight of hydrogen peroxide, about 0.1 part by weight of polyoxyalkylene alkyl aryl phosphate compound represented by a following chemical formula 1, and 500 parts by weight of deionized water. The SSW2000 included silica as an abrasive and ferricyanide compound as an oxidizing agent.

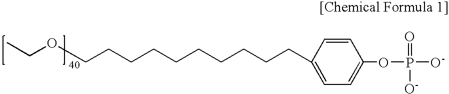

### EXAMPLES 2 TO 7

Slurry compositions were prepared by performing a process substantially identical to that of Example 1 except for the content of the polyoxyalkylene alkyl aryl phosphate compound used as an anionic surfactant. The content of the polyoxyalkylene alkyl aryl phosphate compound is shown in a following Table 1.

### COMPARATIVE EXAMPLE

A conventional slurry composition was prepared. Particularly, SSW2000 (trade name manufactured by Microelectronics Co., U.S.A.) slurry composition was prepared.

TABLE 1

| | | | | Polyoxyalkylene |
|---|---|---|---|---|
| | SSW2000 | Hydrogen | Deionized | alkyl aryl |
| | [part | Peroxide [part | Water [part | phosphate [part |
| | by weight] | by weight] | by weight] | by weight] |
| Example 1 | 500 | 66 | 500 | 0.1 |
| Example 2 | 500 | 66 | 500 | 0.2 |
| Example 3 | 500 | 66 | 500 | 0.5 |
| Example 4 | 500 | 66 | 500 | 1.0 |
| Example 5 | 500 | 66 | 500 | 1.5 |
| Example 6 | 500 | 66 | 500 | 2.0 |
| Example 7 | 500 | 66 | 500 | 5.0 |
| Compar- | 500 | 66 | 500 | 0 |
| ative | | | | |
| Example | | | | |

Evaluation of A Polishing Rate of A Tungsten Layer

Polishing rates of tungsten layers were evaluated using the slurry compositions prepared in Examples 1 to 7 and Comparative Example. The polishing rates of the tungsten layers are shown in a following Table 2.

The polishing rates of the tungsten layers were estimated using blanket wafers including the tungsten layers. Each of the blanket wafers was prepared as follows: firstly, a silicon oxide layer having a thickness of about 1,000 Å was formed on a silicon substrate, and then a titanium/titanium nitride layer having a thickness of about 250 Å was formed on the silicon oxide layer. Subsequently, the tungsten layer having a thickness of about 6,000 Å was formed on the titanium/titanium nitride layer.

In polishing the blanket wafers using the slurry compositions prepared in Examples 1 to 7 and Comparative Example, the polishing rates of the tungsten layers were measured. In each polishing process, a flow rate of the slurry composition was about 200 mL/min, a rotation speed of a polishing pad was about 80 rpm, a rotation speed of a substrate was about 45 rpm, and a pressure on the substrate was about 216 horsepower.

TABLE 2

| | Polishing Rate [Å/min] |
|---|---|
| Example 1 | 2,499 |
| Example 2 | 2,289 |
| Example 3 | 2,043 |
| Example 4 | 1,834 |
| Example 5 | 1,640 |
| Example 6 | 1,488 |
| Example 7 | 173 |
| Comparative Example | 2,680 |

As shown in Table 2, it may be noted that as the content of the anionic surfactant in the slurry composition increases, the polishing rate of the tungsten layer is reduced. In particular, since the anionic surfactant may passivate a silica abrasive in the slurry composition, the polishing rate of the tungsten layer may decrease. Therefore, the slurry composition including an excessive amount of the anionic surfactant may not effectively polish a metal layer such as the tungsten layer. The slurry composition may preferably include less than or equal to about 10 parts by weight of the anionic surfactant based on about 1,000 parts by weight of the slurry composition.

Evaluation of Polishing Selectivity Between A Tungsten Layer And An Oxide Layer

Polishing selectivity between a tungsten layer and an oxide layer was estimated using the slurry compositions prepared in Example 3 and Comparative Example.

The polishing selectivity between the tungsten layer and the oxide layer was estimated using blanket wafers respectively including the tungsten layer and the oxide layer. The blanket wafer including the tungsten layer was prepared by forming the tungsten layer having a thickness of about 6,000 Å on a silicon substrate. The blanket wafer including the oxide layer was prepared by forming the oxide layer having a thickness of about 1,000 Å on a silicon substrate.

The blanket wafers were polished using the slurry compositions prepared in Example 3 and Comparative Example for about 60 seconds. In each polishing process, a flow rate of the slurry composition was about 200 mL/min, a rotation speed of a polishing pad was about 80 rpm, a rotation speed of a substrate was about 45 rpm, and a pressure on the substrate was about 216 horsepower. Thicknesses of the tungsten layer and the oxide layer were measured before and after the polishing process, so that polishing rates of the tungsten layer and the oxide layer were obtained. Polishing selectivities were estimated from the polishing rates of the tungsten layer and the oxide layer. The polishing selectivity between the tungsten layer and the oxide layer is shown in a following Table 3.

TABLE 3

| | | Comparative |
|---|---|---|
| | Example 3 | Example |
| Polishing Rate of Oxide Layer [Å/min] | 16 | 29 |
| Polishing Rate of Tungsten Layer [Å/min] | 2,140 | 2,688 |
| Polishing Selectivity | 1:134 | 1:87 |
| (Oxide Layer:Tungsten Layer) | | |

As shown in Table 3, it may be noted that when the polishing process is performed using the slurry composition including the anionic surfactant, both polishing rates of the oxide layer and the tungsten layer are reduced. However, since the anionic surfactant may be strongly adsorbed onto the oxide layer relative to the tungsten layer by an electrostatic attraction, the anionic surfactant may effectively passivate the oxide layer compared with the tungsten layer. Thus, when the slurry composition including the anionic surfactant is used in the polishing process, the polishing rate of the oxide layer may be reduced more than that of the tungsten layer and the polishing selectivity between the tungsten layer and the oxide layer may be enhanced. Therefore, the slurry composition of the present invention may effectively polish the tungsten layer and prevent the oxide layer from being damaged.

Evaluation of A Thickness of A Bit Line Pattern

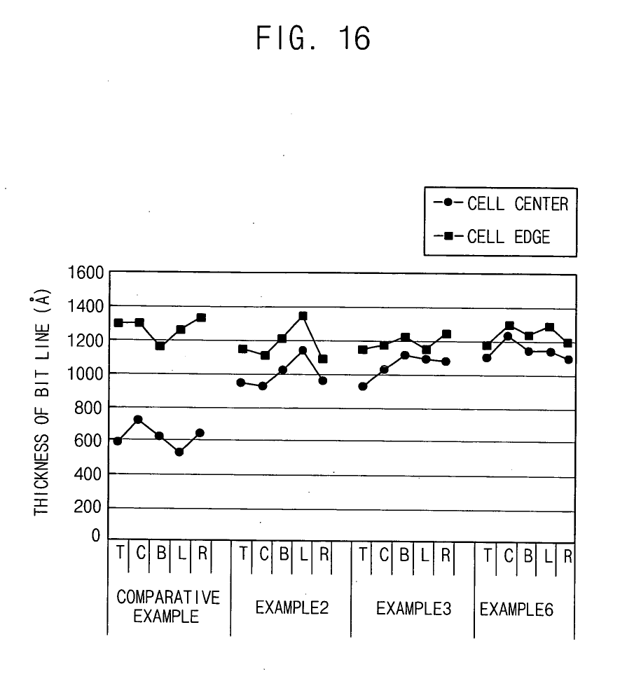

After a bit line pattern was formed on a wafer using the slurry compositions prepared in Examples 2, 3 and 6, and in the Comparative Example, the thickness of the bit line pattern was evaluated for each portion of the wafer. The width of the bit line pattern was about 0.73 μm, and a distance between adjacent bit line patterns was about 0.73 μm. The thickness of the bit line pattern was estimated for five cells on the wafer to confirm the thickness uniformity of the bit line pattern. The five cells were located in a center portion (C), top portion (T), bottom portion (B), left portion (L) and right portion (R) of the wafer based on a flat zone of the wafer. The thickness of the bit line pattern was measured in the center portion and the edge portion of each cell. In addition, the center portion thickness and the edge portion thickness of the bit line pattern were respectively measured, so that dishing of the bit line pattern was estimated from the thickness difference between the center and edge portions of the bit line pattern. The thickness and dishing degree of the bit line pattern in accordance with each portion of the wafer are shown in FIG. 16 and in Table 4.

FIG. 16 is a graph illustrating the thickness of the bit line pattern formed on each portion of the wafer when the bit line pattern is formed on the wafer using slurry compositions prepared in Examples 2, 3 and 6 and Comparative Example.

Referring to FIG. 16, when the bit line pattern is formed by the polishing process using the slurry composition prepared in Comparative Example, the bit line pattern located in the center portion of each cell is much thinner than that of the edge portion of each cell. However, when the bit line pattern is formed through the polishing process using the slurry composition prepared in Examples 2, 3 and 6, the thickness difference of the bit line pattern between the center and the edge portions of each cell is remarkably reduced. Furthermore, as 10 the content of the anionic surfactant in the slurry composition increases, the thickness difference of the bit line pattern between the center and edge portions of each cell becomes smaller.

TABLE 4

| | Measured | Thickness [Å]/Dishing Degree [Å] | | | | |
|---|---|---|---|---|---|---|
| | Portion/Dishing | Top | Center | Bottom | Left | Right |
| Exam- | Cell Center | 1,195 | 1,183 | 1,278 | 1,374 | 1,159 |
| ple 2 | (Pattern Edge) | | | | | |
| | Cell Center | 956 | 932 | 1,027 | 1,135 | 969 |
| | (Pattern | | | | | |
| | Center) | | | | | |
| | Dishing in | 239 | 251 | 251 | 239 | 190 |
| | Cell Center | | | | | |
| | Cell Edge | 1,422 | 1,398 | 1,458 | 1,601 | 1,338 |
| | (Pattern Edge) | | | | | |
| | Cell Edge | 1,148 | 1,112 | 1,207 | 1,339 | 1,099 |
| | (Pattern | | | | | |
| | Center) | | | | | |
| | Dishing in | 274 | 286 | 251 | 262 | 239 |
| | Cell Edge | | | | | |
| Exam- | Cell Center | 1,123 | 1,274 | 1,286 | 1,193 | 1,309 |
| ple 3 | (Pattern Edge) | | | | | |
| | Cell Center | 938 | 1,032 | 1,112 | 1,090 | 1,077 |
| | (Pattern | | | | | |
| | Center) | | | | | |
| | Dishing in | 185 | 242 | 174 | 103 | 232 |
| | Cell Center | | | | | |
| | Cell Edge | 1,378 | 1,402 | 1,436 | 1,380 | 1,480 |
| | (Pattern Edge) | | | | | |
| | Cell Edge | 1,146 | 1,170 | 1,228 | 1,158 | 1,240 |
| | (Pattern | | | | | |
| | Center) | | | | | |
| | Dishing in | 232 | 232 | 208 | 222 | 240 |
| | Cell Edge | | | | | |
| Exam- | Cell Center | 1,482 | 1,589 | 1,482 | 1,494 | 1,470 |
| ple 6 | (Pattern Edge) | | | | | |
| | Cell Center | 1,112 | 1,231 | 1,148 | 1,148 | 1,100 |
| | (Pattern | | | | | |
| | Center) | | | | | |
| | Dishing in | 370 | 358 | 334 | 346 | 370 |
| | Cell Center | | | | | |
| | Cell Edge | 1,589 | 1,721 | 1,637 | 1,685 | 1,589 |
| | (Pattern Edge) | | | | | |
| | Cell Edge | 1,174 | 1,291 | 1,231 | 1,285 | 1,195 |
| | (Pattern | | | | | |
| | Center) | | | | | |
| | Dishing in | 415 | 430 | 406 | 400 | 394 |
| | Cell Edge | | | | | |

As shown in Table 4, it was confirmed that as the content of the anionic surfactant in the slurry composition increases, dishing of the bit line pattern may be severe. The dishing degree of the bit line pattern was obtained from the thickness difference between the center and edge portions of the bit line pattern. In addition, the thickness of the bit line pattern in the center portion of each cell is smaller than that of the edge portion of each cell, because the bit line pattern is densely distributed in the cell center portion compared with that of the cell edge portion. However, when the slurry composition including the anionic surfactant is used in the polishing process, excessive polishing of the bit line pattern formed in a densely distributed region such as the cell center portion may be relieved as illustrated in FIG. 16.

Therefore, the slurry composition of the present invention may prevent excessive polishing of the metal pattern as densely formed. However, when the slurry composition includes an excessive amount of the anionic surfactant, dishing phenomena of the bit line pattern may become worse. The slurry composition preferably includes less than or equal to about 10 parts by weight of the anionic surfactant based on about 1,000 parts by weight of the slurry composition.

According to the present invention, a metal layer formed on a substrate may be effectively polished using the slurry composition. Damage to the metal layer may be prevented, and irregular polishing of the metal layer relative to a pattern density may be prevented to thereby form contacts having a uniform thickness. Therefore, a semiconductor device having improved reliability may be efficiently manufactured, and a productivity of a semiconductor manufacturing process may be enhanced.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A slurry composition comprising:
an acidic aqueous solution having a first pH; and
an anionic surfactant having a second pH lower than or equal to the first pH.

2. The slurry composition of claim 1, wherein the anionic surfactant comprises at least one of a phosphoric acid compound, a phosphate compound, a sulfonic acid compound, a sulfonate compound, a carboxylic acid compound, a carboxylate compound, an acrylic acid compound and an acrylate compound.

3. The slurry composition of claim 2, wherein the anionic surfactant comprises said phosphate compound.

4. The slurry composition of claim 3, wherein the phosphate compound comprises a polyoxyalkylene alkyl aryl phosphate compound.

5. The slurry composition of claim 1, wherein the anionic surfactant comprises an oxyalkylene chain.

6. The slurry composition of claim 5, wherein the oxyalkylene chain is selected from the group consisting of oxymethylene chain, oxyethylene chain, oxypropylene chain and oxybutylene chain.

7. The slurry composition of claim 5, wherein the oxyalkylene chain has a number of oxyalkylene repeating units of from about 20 up to about 60.

8. The slurry composition of claim 1, wherein the anionic surfactant comprises an alkyl chain having from 1 up to 40 carbon atoms.

9. The slurry composition of claim 8, wherein the alkyl chain has from 1 up to 20 carbon atoms.

10. The slurry composition of claim 1, wherein the first pH is from about 1 up to about 6.

11. The slurry composition of claim 1, wherein the second pH is from about 1 up to about 5.

12. The slurry composition of claim 1, wherein the acidic aqueous solution comprises an oxidizing agent, an abrasive and water.

13. The slurry composition of claim 12, wherein the oxidizing agent comprises a peroxide compound, a ferric compound, or a mixture thereof.

14. The slurry composition of claim 13, wherein the peroxide compound comprises at least one of hydrogen peroxide, benzoyl peroxide, calcium peroxide, barium peroxide and sodium peroxide.

15. The slurry composition of claim 13, wherein the ferric compound comprises at least one of ferric nitrate, potassium ferricyanide, ferric phosphate and ferric sulfate.

16. The slurry composition of claim 12, wherein the abrasive comprises at least one of silica, alumina, ceria, zirconia and titania.

17. The slurry composition of claim 1, further comprising a pH-controlling agent.

18. The slurry composition of claim 17, wherein the pH-controlling agent comprises at least one base of potassium hydroxide, ammonium hydroxide, sodium hydroxide, tetramethylammonium hydroxide and choline, or at least one acid selected from the group consisting of sulfuric acid, hydrochloric acid, phosphoric acid, nitric acid and acetic acid.

19. The slurry composition of claim 1, wherein the slurry composition comprises from about 0.001 up to about 10 parts by weight of the anionic surfactant, based on about 1,000 parts by weight of the slurry composition.

20. The slurry composition of claim 19, wherein the slurry composition comprises from about 0.01 up to about 5 parts by weight of the anionic surfactant, based on about 1,000 parts by weight of the slurry composition.

21. A slurry composition comprising:
an acidic aqueous solution including an oxidizing agent, an abrasive and water, the acidic aqueous solution having a first pH; and
an anionic surfactant having a second pH lower than or equal to the first pH.

22. The slurry composition of claim 21, further comprising a pH-controlling agent.

23. A method of polishing an object comprising:
preparing an object;
introducing a slurry composition to a polishing pad, the slurry composition including an acidic aqueous solution having a first pH and an anionic surfactant having a second pH lower than or equal to the first pH; and
polishing a surface of the object by contacting the polishing pad and the surface of the object.

24. The method of claim 23, wherein preparing the object further comprises:
forming an insulation layer on a substrate, the insulation layer including an opening; and
forming a metal layer on the insulation layer to fill the opening.

25. The method of claim 24, wherein polishing the surface of the object is performed until an upper surface of the insulation layer is exposed.

26. The method of claim 24, wherein the insulation layer comprises an oxide.

27. The method of claim 24, wherein the metal layer comprises tungsten.

28. The method of claim 27, wherein the first pH is from about 1 up to about 5.

29. The method of claim 27, wherein the second pH is from about 1 up to about 4.

30. The method of claim 24, wherein the metal layer comprises aluminum or copper.

31. The method of claim 30, wherein the first pH is from about 2 up to about 6.

32. The method of claim 30, wherein the second pH is from about 2 up to about 5.

33. A method of forming a contact in a semiconductor device comprises:
providing a substrate;
forming an insulation layer on said substrate, said substrate including a lower structure;
partially removing the insulation layer to form a contact hole exposing a portion of the lower structure;
forming a conductive layer on the insulation layer which fills the contact hole; and
chemically and mechanically polishing the conductive layer with a slurry composition including an acidic aqueous solution having a first pH, and an anionic surfactant having a second pH lower than or equal to the first pH, until an upper surface of the insulation layer is exposed.

34. The method of claim 33, wherein the insulation layer comprises an oxide.

35. The method of claim 33, wherein the conductive layer comprises at least one of tungsten, aluminum and copper.
